(19) United States
(12) Patent Application Publication
(10) Pub. No.: US 2019/0287918 A1
(43) Pub. Date: Sep. 19, 2019

(54) INTEGRATED CIRCUIT (IC) PACKAGES WITH SHIELDS AND METHODS OF PRODUCING THE SAME

(71) Applicant: Texas Instruments Incorporated, Dallas, TX (US)

(72) Inventors: Woochan Kim, Sunnyvale, CA (US); Vivek Kishorechand Arora, San Jose, CA (US); Anindya Poddar, Sunnyvale, CA (US)

(21) Appl. No.: 15/920,242

(22) Filed: Mar. 13, 2018

(51) Int. Cl. H01L 23/552; H01L 23/495; H01L 21/48; H01L 21/56

(52) U.S. Cl. CPC H01L 23/552; H01L 23/4952; H01L 23/49; H01L 21/561; H01L 21/4842

(57) ABSTRACT

Integrated circuit (IC) packages with shields and methods of producing the same are disclosed. A disclosed IC package includes a lead frame including a die attach pad and a plurality of leads, a die attached to the die attach pad and electrically coupled to the plurality of leads, package encapsulate covering portions of the lead frame and the die, where the package encapsulate includes an indentation at a periphery of the IC package, and where the indentation includes sidewalls. The example IC package also includes a shield in the indentation, where a surface of the shield is coplanar with a surface of the package encapsulate.

### FIELD OF THE DISCLOSURE

This disclosure relates to electromagnetic interference (EMI) shields in integrated circuit (IC) packages.

### BACKGROUND

In recent years, shields, such as electromagnetic interference (EMI) shields, have been provided (e.g., placed and soldered) over and/or assembled to packaged devices (e.g., circuit boards, chips, integrated circuits, etc.) for shielding. However, implementation and assembly of these typically pre-manufactured shields onto packaged devices can be costly and involve significant assembly or integration time. Further, these shields can take significant size and/or occupied volume. In particular, some known assembled shields (e.g., metallic lids) may necessitate tolerance spacing between electrical components and a respective metal shield to prevent unintended shorting. In particular, such spacing can require an additional height or width for clearance to account for component and/or assembly tolerances, thereby necessitating an increased shield size and, thus, a larger overall package size.

### BRIEF DESCRIPTION OF THE DRAWINGS

FIG. 1A illustrates an example wafer to produce the examples disclosed herein.

FIG. 1B is a detailed view of an example die singulated from the wafer shown in FIG. 1A.

FIG. 2 is a flowchart representative of an example method in accordance with the teachings of this disclosure.

FIGS. 3A-3E are cross-sectional views of example steps to provide a shield that is grounded during an integrated circuit (IC) packaging process.

FIG. 4A is a cross-sectional view of shield structures in accordance with the teachings of this disclosure.

FIG. 4B is a cross-sectional view of an example IC package of FIG. 4A.

FIGS. 5A-5E are cross-sectional views of example steps to provide a shield that is isolated from ground.

FIG. 6A is a cross-sectional view of alternative example shield structures in accordance with the teachings of this disclosure.

FIG. 6B is a cross-sectional view of an example IC package of FIG. 6A.

The figures are not to scale. Instead, to clarify multiple layers and regions, the thickness of the layers may be enlarged in the drawings. Wherever possible, the same reference numbers will be used throughout the drawing(s) and accompanying written description to refer to the same or like parts. As used in this patent, stating that any part (e.g., a layer, film, or area) is in any way positioned on (e.g., positioned on, located on, disposed on, or formed on, etc.) another part, indicates that the referenced part is either in contact with the other part, or that the referenced part is above the other part with one or more intermediate part(s) located therebetween. Stating that any part is in contact with another part means that there is no intermediate part between the two parts.

### DETAILED DESCRIPTION

Integrated circuit (IC) packages with shields and methods of producing the same are disclosed. Some IC packages, such as quad flat no-leads (QFN) packages, include metal shields that are usually placed after package assembly (e.g., after an IC packaging process) to reduce electromagnetic interference (EMI) in radio-frequency (RF) applications, for example. However, assembly of these metal shields, which are usually pre-manufactured (e.g., using sheet metal operations such as forming or drawing), can often involve significant processing time, cost and/or steps (e.g., additional manufacturing steps). Further, these shields are often sized relatively larger to provide adequate clearances to electrical components to avoid any potential shorting that may result from manufacturing and/or tolerancing variation(s).

The examples disclosed herein provide a cost-effective and space-saving implementation of metal shields onto IC packages. In particular, the examples disclosed herein define metal shields onto or within (e.g., embedded within) a device package by utilizing a partial depth cut that defines a recess in combination with a metal deposition process (e.g., a layering and/or metallization process). In other words, the examples disclosed herein enable production of metal shields during a packaging process, thereby reducing or eliminating a need for later assembly of a pre-manufactured shield, of which necessitated clearances can result in increasing an overall package size to avoid unintentional shorting.

In some examples, metal is deposited/applied as a metal layer that includes an upper wall (e.g., a lid) and sidewalls of the metal shield formed during a metal deposition process. Accordingly, the sidewalls of the metal shield are aligned and/or coplanar with an indentation and/or step cut defined in a package encapsulate of the package, for example. In some examples, the sidewalls and/or edges of the metal shield are in direct contact or aligned with surfaces of the indentation. Some of the examples disclosed herein utilize the aforementioned partial depth cut to expose a wirebond, to which a metal shield is both electrically and mechanically coupled to the wirebond.

As used herein, the term “package” can refer to a quad flat no-lead (QFN) package (e.g., a very thin quad flat no-lead (VQFN) package, a very very thin quad flat no-lead (WQFN) package, ultrathin quad flat no-lead (UQFN) package, an extremely thin quad flat no-lead (XQFN) package, etc.), a packaged assembly, a microchip, a microprocessor, etc. For example, a die can be assembled onto an IC package and, subsequently, the IC package can be singulated from other IC packages.

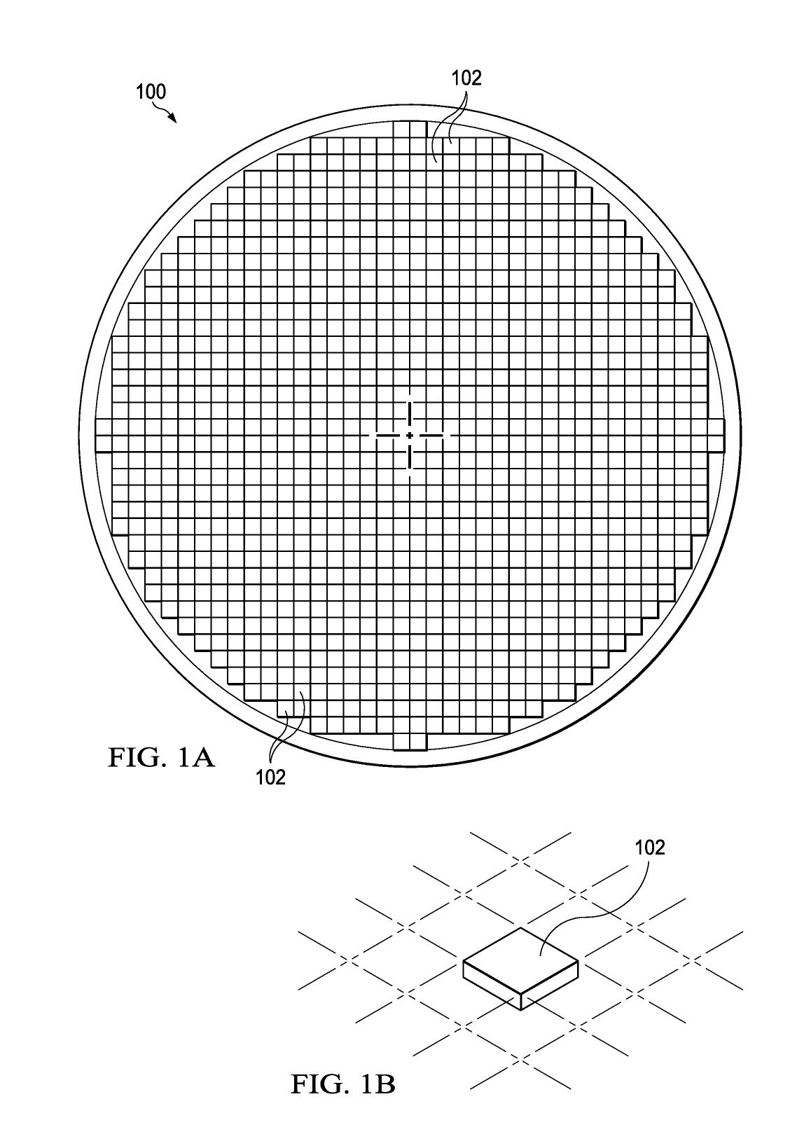

FIG. 1A illustrates an example wafer 100 that may be implemented to produce the examples disclosed herein. The example wafer 100 has a generally flat circular shape and will define a die 102 that is subsequently separated therefrom and assembled to a lead frame to form an IC package.

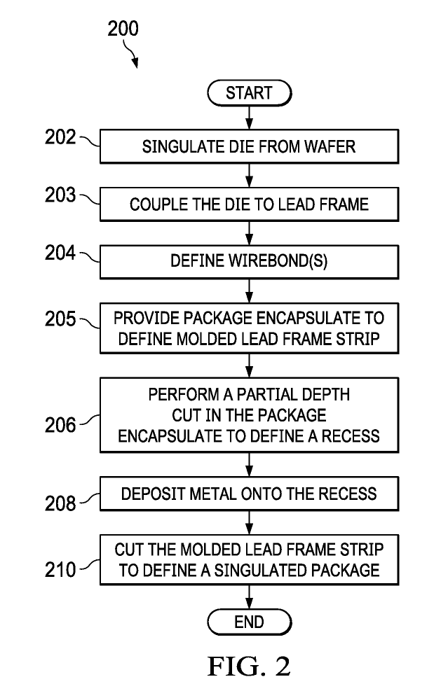

FIG. 1B is a detailed view of one of the example die 102 separated (e.g., singulated) from the wafer 100 shown in FIG. 1A. According to the illustrated example, the die 102 exhibits a generally rectangular shape. As will be discussed in greater detail below in connection with FIGS. 2-6B, the examples disclosed herein enable a metal shield to be defined to cover and/or encapsulate the die 102. In other words, the examples disclosed herein produce shields during an inline packaging process instead of post-packaging assembly of a known pre-manufactured shield, which can be costly and time-consuming.

FIG. 2 is a flowchart representative of an example method 200 in accordance with the teachings of this disclosure. The example method 200 begins as the die 102 are to be separated from the wafer 100 and packaged into respective discrete devices (e.g., QFN packages).

According to the illustrated example, at least one of the die 102 is singulated from the wafer 100 (block 202).

In this example, the die 102 is attached to the lead frame (or a substrate) (block 203). In this example, the die is coupled to a die attach pad of the lead frame.

In some examples, wirebond(s) are defined (block 204). For example, these wirebond(s) can be electrically and mechanically coupled to components (e.g., contact pads, attached die, etc.) and/or extend out of an outer surface (e.g., for external electrical connections as an electrical contact pad).

According to the illustrated example, package encapsulate is provided and/or applied to encapsulate the die and the wirebonds, thereby defining a molded lead frame strip (block 205). In particular, the die and the wirebond(s) are applied or deposited with a package encapsulate, substrate and/or mold compound, for example.

Next, a partial depth cut is performed in the package encapsulate to define a recess (e.g., a groove, a perimeter groove, a cut channel, etc.) in the molded lead frame (block 206). In particular, the molded lead frame of the illustrated example is drilled, machined and/or sawed to define a partial depth cut recess, which does not extend through a full depth. Additionally or alternatively, an etching process (e.g., a chemical etching process, a light etching process, a mechanical etching process, etc.) is implemented to define the recess.

According to the illustrated example, metal is deposited onto the recess (block 208). In this example, the metal is deposited as a metal layer onto a bottom surface of the recess, a sidewall of the recess and a surface or area surrounding an opening of the recess.

In some examples, a bottom surface of the recess of the molded lead frame strip is cut by a full depth cut process to separate at least one package therefrom (block 210) and the process ends. In particular, at least a portion of metal deposited onto the bottom surface of the recess is removed during this cutting process. In some examples, cutting the recess defines a flange edge of the metal shield. Additionally or alternatively, a substrate or other layer beneath the bottom surface of the recess is also removed in this cutting process. In other examples, the full depth cut is not utilized.

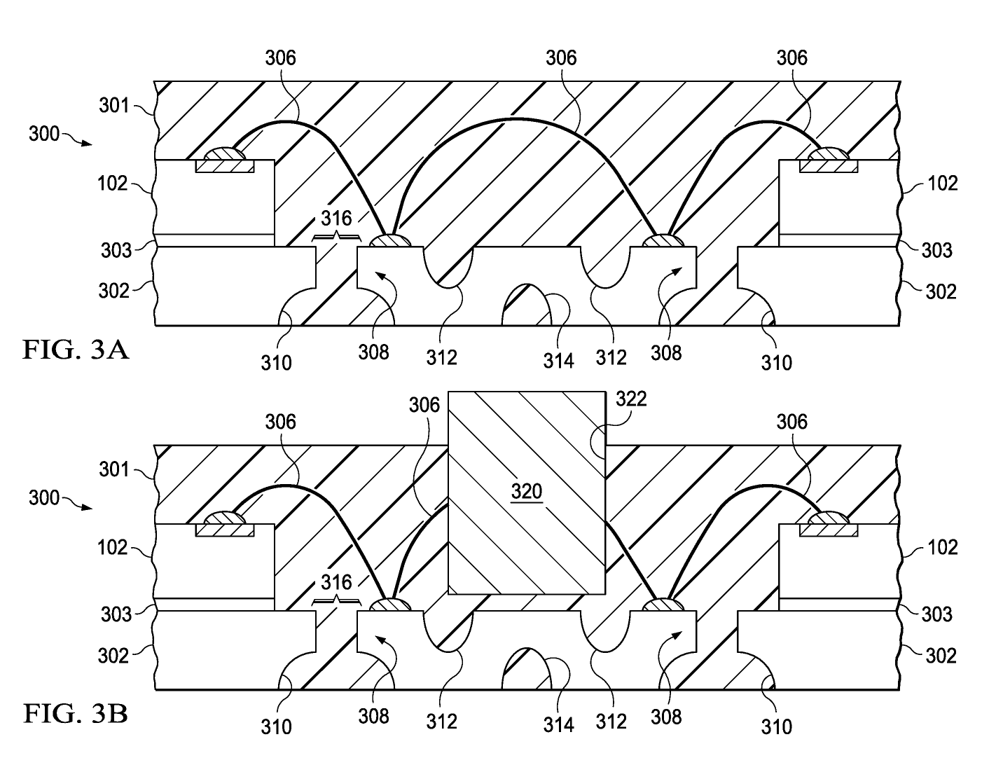

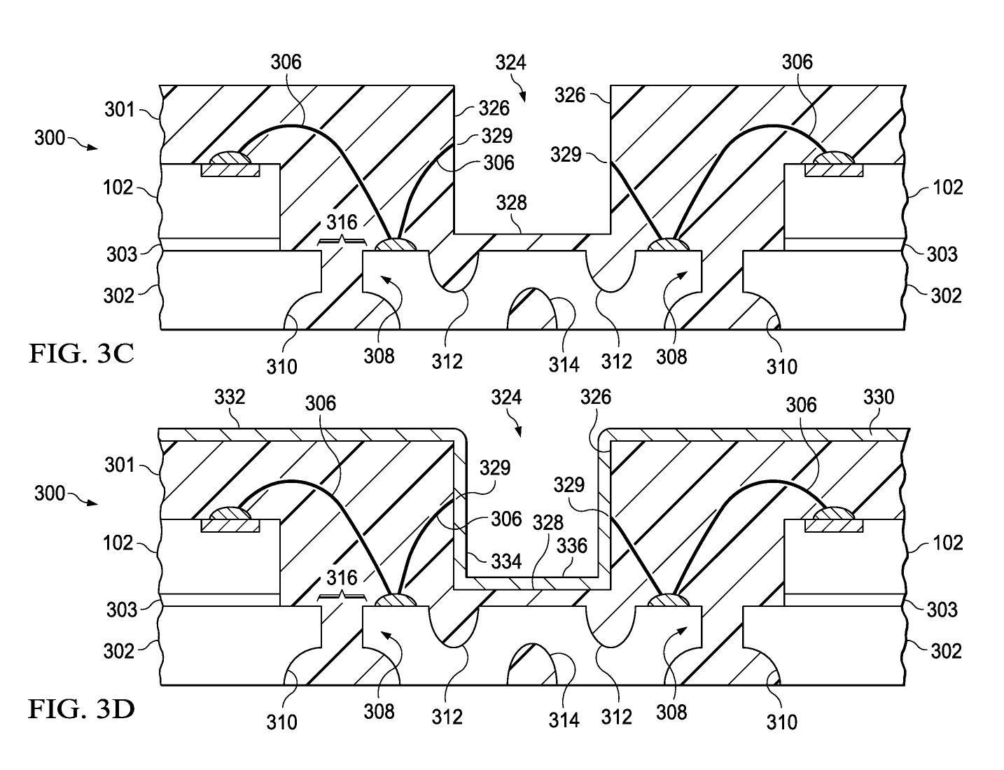

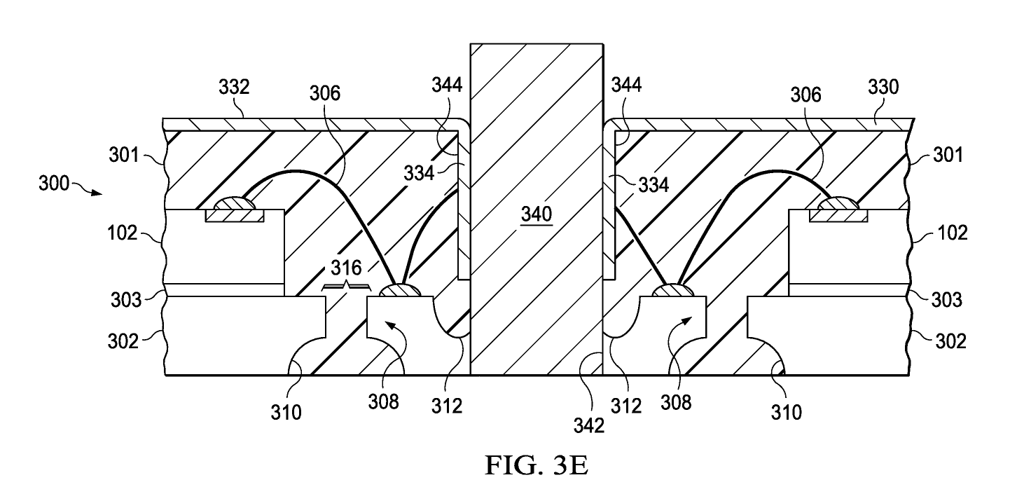

FIGS. 3A-3E are cross-sectional views of example steps to provide a shield during an IC packaging process using the example method 200 to define grounded shields. Turning to FIG. 3A, a molded lead frame 300 is shown. In this example, the molded lead frame 300 is to be provided with at least one metal shield that is grounded (e.g., for EMI shielding purposes). The molded lead frame 300 of the illustrated example includes a package encapsulant (e.g., a substrate, a mold) 301, a frame (e.g., a lead frame, device substructure, etc.) 302, a die attach pad (e.g., a die contact pad) 303, the die 102, and wirebonds (e.g., wirebonds defined via a wirebonding device) 306 routed through the package encapsulate 301.

In this example, the frame 302 includes grounding portions (e.g., grounding sections, grounding pads, etc.) 308, lower indentations (e.g., notches, curved openings, etc.) 310 and upper indentations 312. In some examples, the frame 302 also includes an intermediate indentation (e.g., a center indentation) 314. According to the illustrated example, structures or portions of the frame 302 are separated by gaps 316. In this example, the frame 302 exhibits a generally w-shaped structure to facilitate clearances and/or contacts with interconnects or other components/features.

According to the illustrated example, the wirebonds 306 couple the die 102 to respective ones of the grounding portions 308. In particular, the wirebonds 306 extend both along a depth and lateral width (in the view of FIG. 3A) within the package encapsulate 301 to electrically and mechanically couple various components of the molded lead frame 300.

The die 102 of the illustrated example is coupled to the die attach pad 303 of the lead frame 302.

Turning to FIG. 3B, a cutter 320 is depicted creating a first cut 322 through the package encapsulate 301. In particular, the first cut 322 is a partial depth cut in this example because the cut 322 does not extend through an entire depth of the molded lead frame 300. As a result of the cut 322, at least one of the wirebonds 306 is exposed by the first cut 322. According to the illustrated example, the first cut 322 extends through a partial depth of the package encapsulate 301, but does not extend to the lead frame 302. In other examples, the first cut 322 at least partially extends into a portion of the frame 302. In some examples, the first cut 322 extends approximately 40-60 microns (μm) (e.g., 50 μm) above the lead frame 302 with a width of approximately 500-1100 μm (e.g., 800 μm).

FIG. 3C depicts a step in which the cutter 320 described in connection with FIG. 3B has been removed to reveal exposed surfaces of a recess (e.g., a channel, a groove, etc.) 324. In particular, the recess 324 includes sidewalls 326 and a bottom surface 328 defined by the cut 322. Further, the sidewalls 326 also include exposed surfaces/edges 329 of the wirebonds 306.

Turning to FIG. 3D, a metal deposition step is depicted. According to the illustrated example, a metal (e.g., a metal layer, a metal coating, a metal support structure, etc.) 330 is applied onto exposed surfaces defined by the cutter 320 of FIG. 3B and, thus, coupled to the wirebonds 306. In particular, the exposed surfaces/edges 329 are electrically and mechanically coupled to the metal 330 in this example. The metal 330, which is applied as a layer in this example, includes a top portion 332, a sidewall portion 334 that covers the sidewalls 326, and a bottom portion 336 that covers the bottom surface 328. In other words, the metal 330 of the illustrated example is applied to and around the recess 324 to define a notch-like shape of the metal 330. In some examples, the metal 330 is at least partially composed of gold, copper, tin, silver, nickel, titanium, palladium and/or aluminum. In some examples, a thickness of the metal 330 is approximately 1-5 μm (e.g., 3 μm).

While the metal 330 is applied as a metal layer in this example, the metal 330 may be deposited by a sputter process, an evaporation process, deposition, a lithography process, and/or a printing process, etc. In some examples, the metal 330 is applied with openings at different positions and/or geometries (e.g., the metal 330 includes notches, holes and/or openings at different positions or regions). Additionally or alternatively, the metal 330 is applied at different thickness with respect to different portions of the molded lead frame 300.

Turning to FIG. 3E, a cutter 340 defines a second cut 342 that is a full depth cut to remove at least a portion of the metal 330 along with portions of the package encapsulate 301 and the frame 302. Accordingly, a recess or indentation 344 of the package encapsulate is defined in which the sidewall portion 334 of the metal 330 is disposed, aligned and/or positioned. In some examples, the cutter 340 of the illustrated example has a relatively smaller overall width (e.g., diameter) than the cutter 320 of FIG. 3B (e.g., a width that is 70-90% the width of the cutter 320). In some examples, a full depth cut is not performed. Additionally or alternatively, in some examples, the metal 330 can define a shield that is embedded within or beneath a substrate and/or package encapsulate material. In such examples, an additional substrate layer and/or package encapsulate is deposited above the metal 330 during production. In some examples, the second cut 342 is approximately 400-800 μm (e.g., 600 μm).

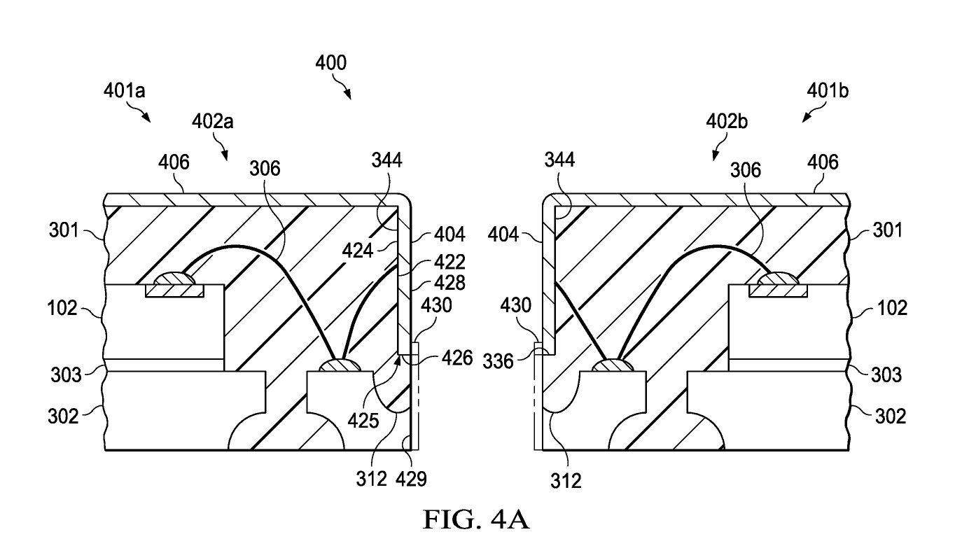

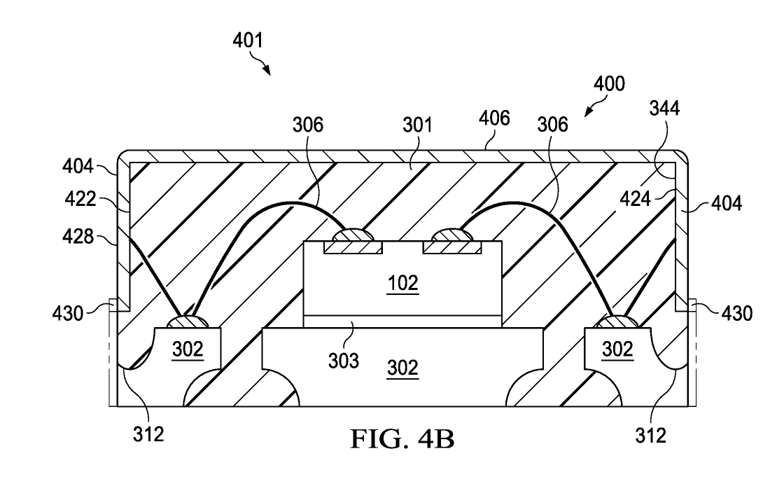

FIG. 4A is a cross-sectional view of shield structures (e.g., shields, integrated shields, etc.) 400 in accordance with the teachings of this disclosure. According to the illustrated example, the shield structures 400 are defined by processes described above in connection with FIGS. 2-3E.

As can be seen in the illustrated example of FIG. 4A, portions of two singulated packages 401 (hereinafter described as packages, 401a, 401b, etc.) are shown separated from one another. In this example, both of the packages 401a, 401b include fully-defined IC package shields 402 (hereinafter described as shields 402a, 402b) with respective sidewalls 404 as well as upper walls (e.g., lids) 406. In other words, each of the shields 402a, 402b significantly envelopes and/or surrounds structures (e.g., electrical components, integrated circuits, etc.) and the package encapsulate 301 of the respective packages 401a, 401b while providing significant mechanical support and/or rigidity thereto. In this example, both of the shields 402a, 402b are electrically and mechanically coupled to the respective wirebonds 306. Further, as can be seen in the illustrated example of FIG. 4A, the indentation 312 enables clearance from the frame to the respective lower portions 336 to reduce (e.g., eliminate) unintended shorting between the frame 302 and one of the respective shields 402a, 402b.

According to the illustrated example, the recess 344 shown in FIG. 3E defines a generally jog-shaped indentation or stepped profile of the package encapsulate 301. In particular, an outwardly facing sidewall 422 of the package encapsulate 301 aligns (e.g., fully contacts and aligns) with an inner surface 424 of the respective shield 402a, 402b. Likewise, in this example, a bottom edge 425 of the respective shield 402a, 402b shield is aligned with (e.g., fully contacts with) a surface (e.g., base surface, a base wall, an upward facing surface in the view of FIG. 4A) 426 of the package encapsulate 301. In this example, singulating the packages 401a, 401b from one another (e.g., via a cutting process) aligns an outer edge 428 of the respective shield 402a, 402b with a cut peripheral surface 429 (e.g., caused by a single dull depth cut process) at a periphery of the respective ones of the packages 401a, 401b.

In some examples, the sidewalls 404 include a respective flange (e.g., a bottom flange, a support flange, etc.) 430. In particular, the flanges 430 can be defined by appropriately sizing the cutter 340 (e.g., implementing a relatively smaller overall width of the cutter 340 in comparison to the cutter 320).

In this example, the shields 402a, 402b are defined having a generally rectangular footprint. However, the shields 402a, 402b may exhibit any appropriate shaped footprint (e.g., round, circular, triangular, pentagonal, hexagonal, polygonal, curved, consisting of multiple splines, etc.). In some examples, at least one of the shields 402a, 402b includes a ramped or trapezoidal structure or feature (e.g., an etched inclined surface of a substrate or encapsulate material that is covered by a metal layer).

FIG. 4B is a cross-sectional view of the singulated package 401 of FIG. 4A. According to the illustrated view of FIG. 4B, the sidewall 404 surrounds the entire periphery (e.g., four sides) of the singulated package 401. In some examples, the flange 430 also surrounds the entire periphery of the singulated package 401. As can be seen in the example of FIG. 4B, the upper wall 406 defines a lid that is mechanically coupled (e.g., by being an integral metal structure defined during a single metal deposition process) to all of the sidewalls 404 in this example.

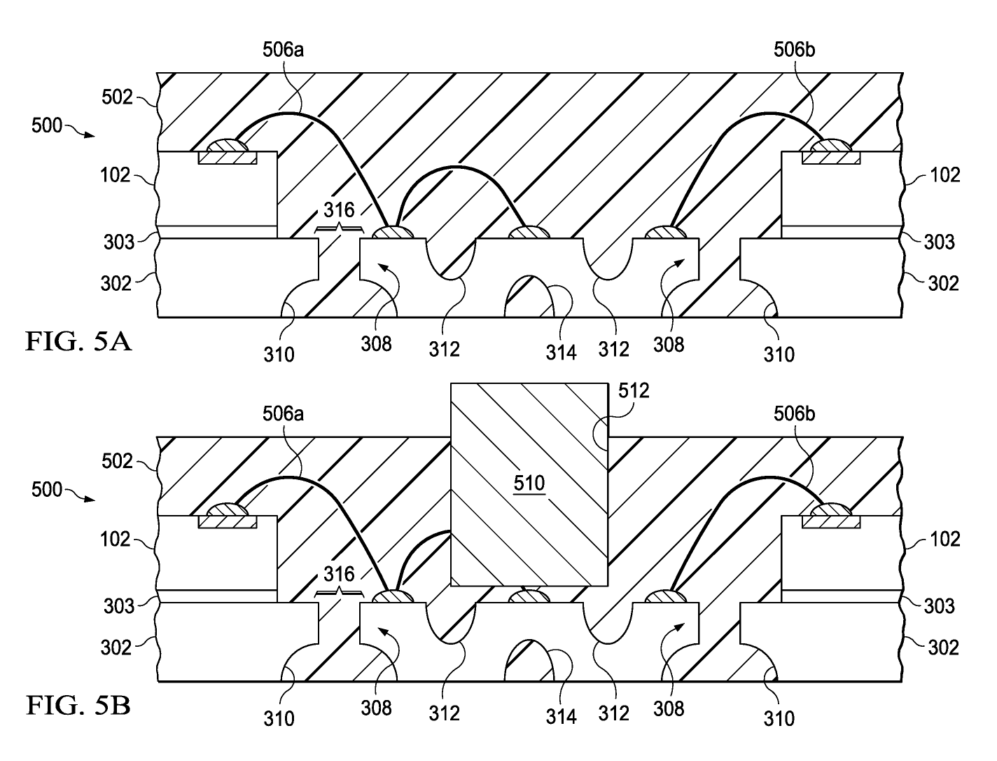

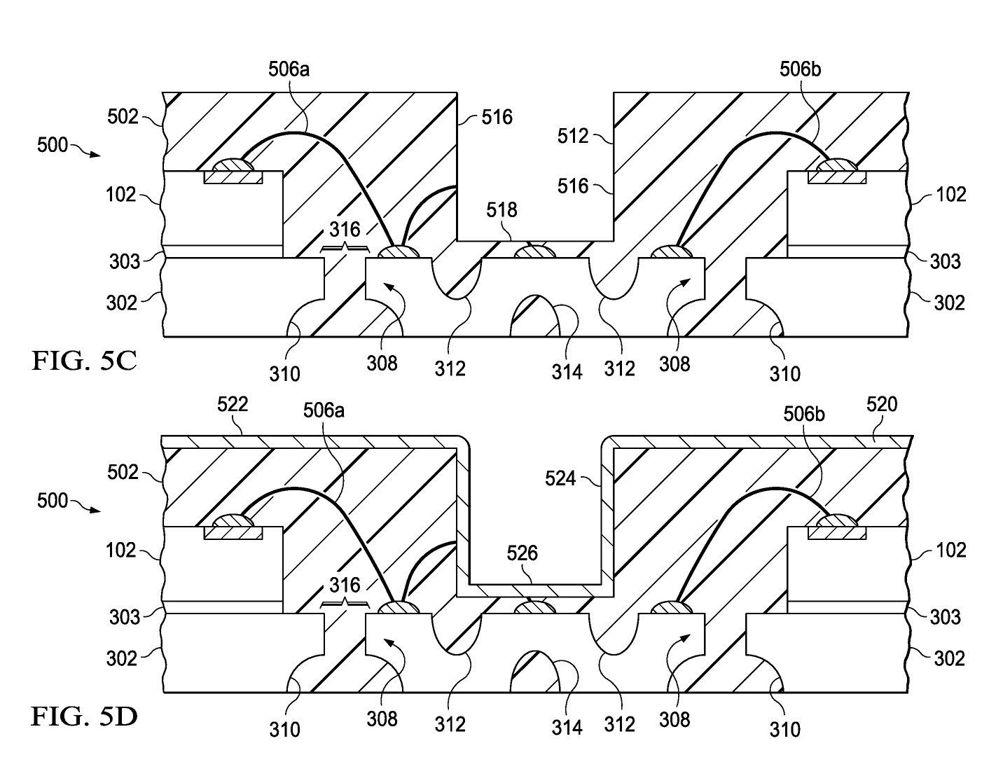

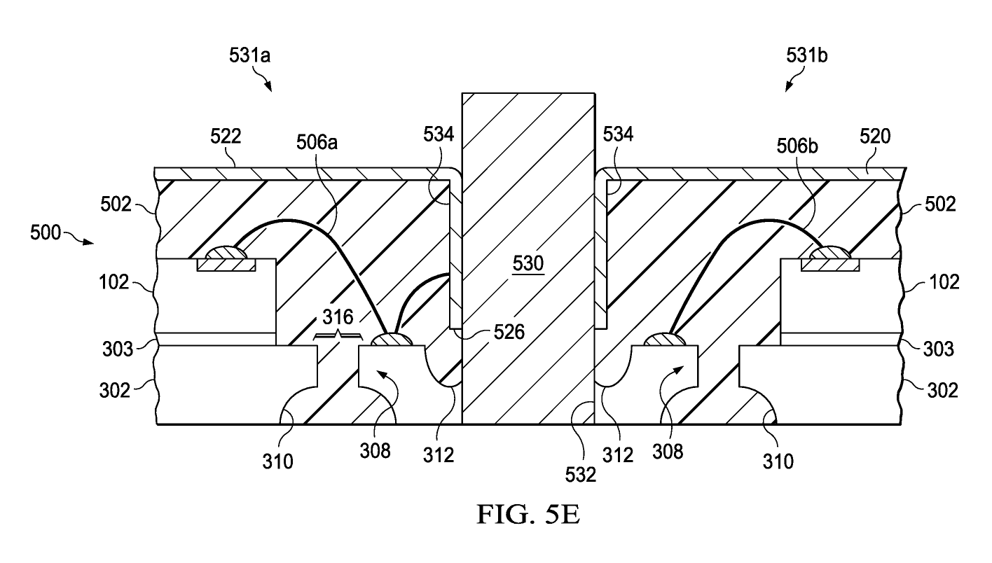

FIGS. 5A-5E are cross-sectional views of example steps to produce an integrated metal shield that can be isolated from ground and/or electrical interconnects, for example. Turning to FIG. 5A, a molded lead frame 500 that is similar to the molded lead frame 300 of FIG. 3A is shown. The molded lead frame 500 includes a package encapsulate (e.g., a substrate, a mold, etc.) 502 having wirebonds 506 (hereinafter described as wirebonds 506a, 506b) defined within. However, in contrast to the molded lead frame 300, the rightmost wirebond 506b does extend from the ground portion 308 of the frame 302 away from the rightmost die 102 and, thus, the corresponding ground portion 308 is not to be grounded in this example. In some examples, at least one of the wirebonds 506 provides a voltage signal contact (e.g., a contact to a voltage signal line) to a metal shield.

FIG. 5B depicts a cutter 510 defining a first cut 512, which is a partial depth cut in this example, to expose the wirebonds 506a in a manner similar to that described above in connection with FIG. 3B. However, in this example, the wirebonds 506b are not exposed by the cut 512.

Turning to FIG. 5C, exposed sidewalls 516 as well as an exposed bottom surface 518 are shown. In the illustrated example of FIG. 5C, the wirebonds 506a are exposed by the first cut 512 while the wirebonds 506b of the right side of FIG. 5C are not exposed by the first cut 512.

FIG. 5D depicts providing (e.g., depositing) a metal 520 to surfaces of the package encapsulate 502. As a result, a top surface 522, a sidewall 524 and a bottom surface 526 are defined. According to the illustrated example, the metal 520 is deposited/applied as a layer with a relatively uniform thickness across a span of the molded lead frame 500. The example metal 520 is coupled to the wirebonds 506a. In contrast, the wirebonds 506b are not coupled to the metal 520 in this example.

Turning to FIG. 5E, a cutter 530 is shown defining a full depth cut 532, thereby defining singulated packages 531 (hereinafter 531a, 531b). The example cut 532 has a relatively smaller width or diameter than the cutter 510 of FIG. 5B. In this example, the cut 532 singulates/separates the packages 531a, 531b from one another. The cut 532 defines an indentation and/or stepped/jogged profile 534 of the package encapsulate 502. In other examples, the cut 532 is only a partial depth cut in which at least a portion of the bottom surface 526 is removed.

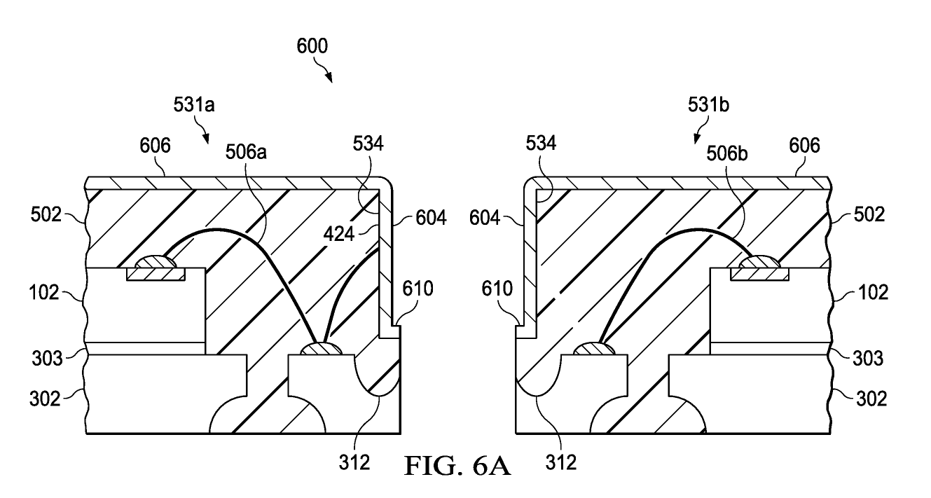

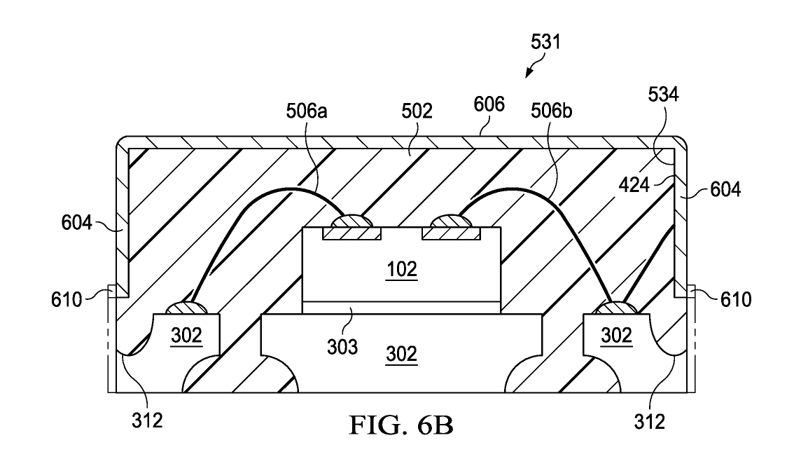

FIG. 6A is a cross-sectional view of alternative example shield structures 600. As can be seen in the view of FIG. 6A, portions of the example singulated packages 531a, 531b of FIG. 5E are shown. The shield structures 600 include shields 602 (hereinafter shields 602a, 602b) with sidewalls 604 and top surfaces 606. In this example, the sidewalls 604 are positioned in and/or aligned by the corresponding indentations 534 of the package encapsulate 502. In contrast to the examples of FIGS. 3A-5B, the wirebonds 506b are not coupled to the corresponding shield 602b in this example. In contrast, exposed signal contacts/surfaces (e.g., input/output (I/O) signal contacts) of the wirebonds 506a are coupled to the respective shield 602a, however. In this example, the shield 602a of the illustrated example is used to transmit and/or propagate an electrical signal. In some examples, a flange 610 is defined based on cutting the shields 602a, 602b during a singulation process.

FIG. 6B is a cross-sectional view of the singulated package 531 of FIG. 6A. In this example, the sidewalls 604 surround a periphery of one the example shield structures 600. In some examples, the flanges 610 also surround the aforementioned periphery.

From the foregoing, it will be appreciated that example methods, apparatus and articles of manufacture have been disclosed that enable production of shields during packages processes to reduce or eliminate a need for costly placed/assembled shields, which may also entail additional volume/spacing to avoid potential component shorting. Thus, the examples disclosed herein also enable more compact shielding structures (e.g., EMI shielding structures) than known placed shields.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

1. An integrated circuit (IC) package comprising:
a lead frame including a die attach pad and a plurality of leads;
a die attached to the die attach pad and electrically coupled to the plurality of leads; package encapsulate covering portions of the lead frame and the die, the package encapsulate including an indentation at a periphery of the IC package, the indentation including sidewalls; and
a shield in the indentation, wherein a surface of the shield is coplanar with a surface of the package encapsulate, and wherein the shield is electrically coupled to at least one lead of the plurality of leads via a wire bond.

2. The IC package as defined in claim 1, wherein the plurality of leads are exposed on sides of the IC package.

3. The IC package as defined in claim 2, wherein the sidewalls are in a plane parallel to a plane of the plurality of leads that are exposed on the sides of the IC package.

4. The IC package as defined in claim 1, wherein the die is electrically coupled to the plurality of leads via wirebonds.

5. The IC package as defined in claim 1, wherein the shield is electrically coupled to the die.

6. The IC package as defined in claim 1, wherein a surface of the die attach pad is exposed from the IC package.

7. The IC package as defined in claim 1, wherein the at least one lead of the plurality of leads is connected to a ground voltage.

8. The IC package as defined in claim 1, wherein the indentation includes a surface that couples the sidewall to the surface of the package encapsulate.

9. The IC package as defined in claim 1, wherein the shield is approximately between 2 to 4 microns thick.

10. The IC package as defined in claim 1, wherein the shield includes a flange surrounding the periphery.

11-19. (canceled)

20. An integrated circuit (IC) package comprising:
a die attach pad and a plurality of leads;
a die attached to the die attach pad and electrically coupled to the plurality of leads;
mold compound covering portions of the lead frame and the die, the mold compound including an indentation at a periphery of the IC package; and
a shield in the indentation, wherein the shield includes an inverted U shape from a cross-sectional view of the IC package.

21. The IC package of claim 20, wherein a surface of the shield is coplanar with a surface of the package encapsulate.

22. The IC package of claim 20, wherein the shield is electrically coupled to at least one lead of the plurality of leads via a wire bond.

23. The IC package of claim 20, wherein the shield fully covers a top side of the IC package.

24. An integrated circuit (IC) package comprising:
a die attach pad and a plurality of leads;
a die attached to the die attach pad and electrically coupled to the plurality of leads;
package encapsulate covering portions of the lead frame and the die, the package encapsulate including an indentation at a periphery of the IC package; and
a shield in the indentation and fully covering a top surface of the IC package.

25. The IC package of claim 24, wherein the shield includes an inverted U shape from a cross-sectional view of the IC package.

26. The IC package of claim 24, wherein a surface of the shield is coplanar with a surface of the package encapsulate.

27. The IC package of claim 24, wherein the shield is electrically coupled to at least one lead of the plurality of leads via a wire bond.

28. The IC package of claim 24, wherein a surface of the die attach pad is exposed from the IC package.
